(19) United States
(12) Patent Application Publication
(10) Pub. No.: US 2026/0047005 A1
(43) Pub. Date: Feb. 12, 2026

(54) CIRCUIT BOARD AND IMAGE FORMING APPARATUS

(71) Applicant: CANON KABUSHIKI KAISHA, Tokyo (JP)

(72) Inventor: TAKAHIRO HARAGUCHI, Chiba (JP)

(21) Appl. No.: 19/293,551

(22) Filed: Aug. 7, 2025

(30) Foreign Application Priority Data
Aug. 9, 2024 (JP) 2024-134362

(51) Int. Cl. H05K 1/11; H05K 1/18

(52) U.S. Cl. CPC H05K 1/111; H05K 1/181

(57) ABSTRACT

A circuit board having a first surface includes a first electronic part mounted on the first surface and comprising a first terminal and a second terminal, a first pad which is placed on the first surface and to which the first terminal of the first electronic part is connected, a second pad which is placed on the first surface and to which the second terminal of the first electronic part is connected, and a third pad and a fourth pad which are placed on the first surface and to which terminals of a second electronic part are connectable, the second electronic part being a different part from the first electronic part, wherein the third pad is placed between the first pad and the second pad in a first direction along the first surface.

### BACKGROUND

### Field of the Technology

The present disclosure relates to a circuit board on which electronic parts are mounted, and an image forming apparatus in which the circuit board is installed.

### Description of the Related Art

In the field of circuit board, one part, selected exclusively from a plurality of electronic parts which are compatible with a specific electrical standard and mutually interchangeable, is mounted on a circuit board. In Japanese Patent Application Laid-open No. 2001-320156, there is disclosed a circuit board (printed board) on which pads for an electronic part that is relatively small in package size are placed between pads for an electronic part that is relatively large in package size.

The pad arrangement described in the related art is only applicable in limited cases, such as when there is a certain degree of difference in package size. Accordingly, it is difficult in the related art to arrange pads in a way that narrows the mounting region. That is, there is a problem in that the circuit board ends up being large in size.

### SUMMARY

A circuit board having a first surface according to one embodiment of the present disclosure includes a first electronic part mounted on the first surface and comprising a first terminal and a second terminal, a first pad which is placed on the first surface and to which the first terminal of the first electronic part is connected, a second pad which is placed on the first surface and to which the second terminal of the first electronic part is connected, and a third pad and a fourth pad which are placed on the first surface and to which terminals of a second electronic part are connectable, the second electronic part being a different part from the first electronic part, wherein the third pad is placed between the first pad and the second pad in a first direction along the first surface, wherein the second pad is placed between the third pad and the fourth pad in the first direction, and wherein the third pat is not in contact with the first electronic part.

An image forming apparatus according to another embodiment of the present disclosure includes an image forming unit configured to form an image on a recording material, and a controller configured to control the image forming unit, wherein the controller includes a circuit board on which a first electronic part is mounted and a second electronic part is not mounted, the circuit board having a first surface, wherein the first electronic part is mounted on the first surface and includes a first terminal and a second terminal, wherein the circuit board includes a first pad which is placed on the first surface and to which the first terminal of the first electronic part is connected, a second pad which is placed on the first surface and to which the second terminal of the first electronic part is connected, and a third pad and a fourth pad which are placed on the first surface and to which terminals of a second electronic part are connectable, wherein the third pad is placed between the first pad and the second pad in a first direction along the first surface, wherein the second pad is placed between the third pad and the fourth pad in the first direction, and wherein the third pat is not in contact with the first electronic part.

Features of the present disclosure will become apparent from the following description of embodiments with reference to the attached drawings. The following description of embodiments is described by way of example.

### BRIEF DESCRIPTION OF THE DRAWINGS

FIG. 1A and FIG. 1B are explanatory diagrams for illustrating a shape of an electronic part.

FIG. 2 is an explanatory diagram of a region for mounting an electronic part.

FIG. 3A and FIG. 3B are explanatory diagrams of arrangement of pads.

FIG. 4 is an explanatory diagram of another example of the region for mounting the electronic part.

FIG. 5 is an explanatory diagram of still another example of the region for mounting the electronic part.

FIG. 6 is an explanatory diagram of an image forming apparatus.

FIG. 7 is a configuration diagram of a controller power supply unit.

### DESCRIPTION OF THE EMBODIMENTS

Now, referring to the accompanying drawings, description is given of at least one embodiment of the present disclosure.

### Configuration of Electronic Part

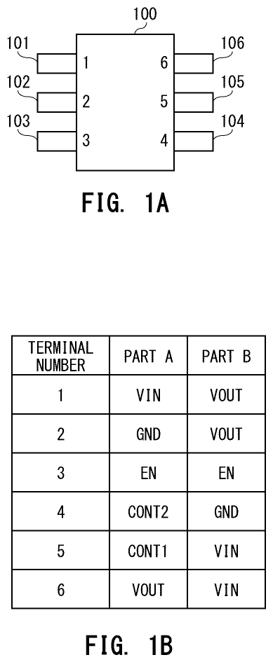

FIG. 1A and FIG. 1B are explanatory diagrams of a shape of an electronic part mounted on a circuit board according to the at least one embodiment. As illustrated for exemplification in FIG. 1A, an electronic part 100 has six, for example, terminals (six pins). The electronic part 100 is, for example, a Small Outline Package (SOP). The electronic part 100 includes, therein, among others, a semiconductor device for executing predetermined processing. Each of the terminals has a function for performing power supply, signal input, signal output, grounding, or the like with respect to a semiconductor element inside the electronic part 100.

A first terminal 101 of the electronic part 100 has a function assigned to a terminal number 1. A second terminal 102 of the electronic part 100 has a function assigned to a terminal number 2. A third terminal 103 of the electronic part 100 has a function assigned to a terminal number 3. A fourth terminal 104 of the electronic part 100 has a function assigned to a terminal number 4. A fifth terminal 105 of the electronic part 100 has a function assigned to a terminal number 5. A sixth terminal 106 of the electronic part 100 has a function assigned to a terminal number 6.

The first terminal 101, the second terminal 102, and the third terminal 103 are provided on the same side of a package of the electronic part 100. The fourth terminal 104, the fifth terminal 105, and the sixth terminal 106 are provided on the same side of the package of the electronic part 100. The side of the package of the electronic part 100 on which the first terminal 101, the second terminal 102, and the third terminal 103 are provided and the side of the package of the electronic part 100 on which the fourth terminal 104, the fifth terminal 105, and the six terminal 106 are provided are opposed to each other.

FIG. 1B is a table for showing exemplary functions assigned to the respective terminals in a case in which the electronic part 100 is a part A and a case in which the electronic part 100 is a part B. Although two types (the part A and the part B) are described here as types of the electronic part 100, there may be three or more types as types of the electronic part 100. An example in which the part A and the part B are each configured to output a voltage that depends on a power supply voltage input thereto is described. The part A and the part B may be configured to output the exact same voltage as the input power supply voltage, or output a voltage having a voltage value converted from that of the input power supply voltage.

In the case in which the electronic part 100 is the part A, functions assigned to the respective terminals are as follows. The first terminal 101 functions as a power supply input terminal VIN. The second terminal 102 functions as a ground terminal GND. The third terminal 103 functions as an input terminal EN for a control signal. The fourth terminal 104 functions as a second setting terminal Cont2 for setting a function of the part A. The fifth terminal 105 functions as a first setting terminal Cont1 for setting a function of the part A. The sixth terminal 106 functions as a power supply output terminal VOUT.

The second setting terminal Cont2 assigned to the fourth terminal 104 and the first setting terminal Cont1 assigned to the fifth terminal 105 are terminals for setting functions different from each other to the part A. The fifth terminal 105 (the first setting terminal Cont1) is a terminal connectable to the sixth terminal 106 (the power supply output terminal VOUT).

In the case of the part A, the electronic part 100 operates, for example, as follows. In a case in which a control signal of a predetermined logical value (for example, “High”) is input from, for example, the third terminal 103, the electronic part 100 outputs, from the sixth terminal 106, a voltage input to the power supply input terminal VIN. In a case in which a control signal of a reverse logical value (for example, “Low”) is input from the third terminal 103, the electronic part 100 does not output, from the sixth terminal 106, a voltage input to the power supply input terminal VIN.

In the case in which the electronic part 100 is the part B, functions assigned to the respective terminals are as follows. The first terminal 101 functions as a first power supply output terminal VOUT. The second terminal 102 functions as a second power supply output terminal VOUT. Although “first” and “second” are used to discriminate the power supply output terminals from each other for descriptive purposes, the first power supply output terminal VOUT and the second power supply output terminal VOUT output the same output voltage VOUT. The third terminal 103 functions as an input terminal EN for a control signal. The fourth terminal 104 functions as a ground GND. The fifth terminal 105 functions as a first power supply input terminal VIN. The sixth terminal 106 functions as a second power supply input terminal VIN. Although “first” and “second” are used to discriminate the power supply input terminals from each other for descriptive purposes, the same input voltage VIN is input to the first power supply input terminal VIN and the second power supply input terminal VIN.

In the case of the part B, the electronic part 100 operates, for example, as follows. In a case in which a control signal of a predetermined logical value (for example, “High”) is input from, for example, the third terminal 103, the electronic part 100 outputs, from the first terminal 101 and the second terminal 102, a voltage input to the first power supply input terminal VIN and the second power supply input terminal VIN. In a case in which a control signal of a predetermined logical value (for example, “Low”) is input from the third terminal 103, the electronic part 100 does not output, from the first terminal 101 and the second terminal 102, a voltage input to the first power supply input terminal VIN and the second power supply input terminal VIN.

Thus, functions assigned to some of the terminals of the part A and functions assigned to some of the terminals of the part B are the same as each other, and functions assigned to the rest of the terminals of the part A and functions assigned to the rest of the terminals of the part B differ from each other. The part A and the part B may differ from each other in the number of terminals or the arrangement of terminals. For example, the part B may further include a seventh terminal placed on the same side as a side on which the first terminal 101, the second terminal 102, and the third terminal 103 are placed, and an eighth terminal placed on the same side as a side on which the fourth terminal 104, the fifth terminal 105, and the sixth terminal 106 are placed. In this case, the addition of the seventh terminal and the eighth terminal makes the part B larger in size than the part A that much.

### Configuration of Circuit Board

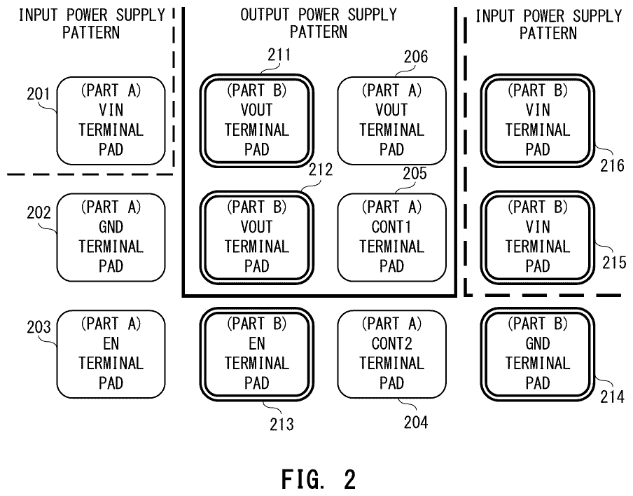

FIG. 2 is an explanatory diagram of a region for mounting the electronic part 100 out of regions of the circuit board on which the electronic part 100 is mounted. In the region for mounting the electronic part 100, pads to which the respective terminals of the electronic part 100 are to be connected are placed in a manner that enables mounting of the electronic part 100 irrespective of whether the electronic part 100 is the part A or the part B. Exemplary arrangement of those pads is illustrated in FIG. 2.

The circuit board according to the at least one embodiment is a printed board configured by, for example, forming a predetermined wiring pattern from a conductor such as copper foil on a mounting surface (first surface) on which the electronic part 100 is mounted, and covering the wiring pattern with a dielectric. Signal transmission and reception, supply of a power supply voltage, and the like are performed by way of the wiring pattern of the conductor among a plurality of electronic parts including the mounted electronic part 100. The pads are resist opening portions configured by exposing, from the dielectric, a wiring pattern (conductor) for soldering the terminals of the electronic part 100 to the circuit board. That is, in the at least one embodiment, openings are formed in a resist that is a dielectric, and define regions that function as the pads. Although the description given in the at least one embodiment takes a case in which the circuit board is a printed board as an example, the circuit board is not limited to a printed board and may be any substrate on which the electronic part 100 can be mounted. The regions that function as the pads may be defined by outer edges of the wiring pattern of the conductor, instead of the openings in the resist.

In FIG. 2, pads 201, 202, 203, 204, 205, and 206 for the part A and pads 211, 212, 213, 214, 215, and 216 for the part B are placed. The first terminal 101 of the part A is to be connected to the pad 201. The second terminal 102 of the part A is to be connected to the pad 202. The third terminal 103 of the part A is to be connected to the pad 203. The fourth terminal 104 of the part A is to be connected to the pad 204. The fifth terminal 105 of the part A is to be connected to the pad 205. The sixth terminal 106 of the part A is to be connected to the pad 206. The first terminal 101 of the part B is to be connected to the pad 211. The second terminal 102 of the part B is to be connected to the pad 212. The third terminal 103 of the part B is to be connected to the pad 213. The fourth terminal 104 of the part B is to be connected to the pad 214. The fifth terminal 105 of the part B is to be connected to the pad 215. The sixth terminal 106 of the part B is to be connected to the pad 216.

In the at least one embodiment, a part of the region for mounting the part A and a part of the region for mounting the part B overlap with each other. Other parts (also referred to as “remainder”) of the part A do not overlap with the region for mounting the part B. That is, the remainder of the part A is positioned outside the region for mounting the part B. The remainder of the part B does not overlap with the region for mounting the part A. Accordingly, in a first direction (left-right direction of FIG. 2) along the mounting surface of the circuit board, the pads 211 to 213 to which the terminals of the part B are to be connected are placed between some of the pads to which the terminals of the part A are to be connected, namely, the pads 201 to 203, and the rest of the pads, namely, the pads 204 to 206. In the first direction, the pads 204 to 206 to which the terminals of the part A are to be connected are also placed between some of the pads to which the terminals of the part B are to be connected, namely, the pads 211 to 213, and the rest of the pads, namely, the pads 214 to 216.

In the example of FIG. 2, the pads 201, 211, 206, and 216 are aligned on a line along the first direction. This arrangement is expressed as “the pads 201, 211, 206, and 216 are placed at the same position in a second direction (top-bottom direction of FIG. 2) intersecting the first direction” in some places. Meanwhile, the pad 201 and the pad 212, for example, are not aligned on the line along the first direction. This arrangement is expressed as “the pad 201 and the pad 212 are placed at different positions in the second direction”in some places.

With the pads arranged in this manner, the part A and the part B are mounted on the circuit board exclusively of each other. Accordingly, in the case of mounting, for example, the part A, the pads 211 to 213 to which the terminals of the part B are to be connected are covered under the part A. Similarly, in the case of mounting the part B, the pads 204 to 206 to which the terminals of the part A are to be connected are covered under the part B.

The pad 201, the pad 215, and the pad 216 to each of which a terminal functioning as the power supply input terminal VIN is connected are connected to an input power supply pattern which is a wiring pattern. A power supply voltage is supplied to each pad by way of the input power supply pattern. The pad 206, the pad 211, and the pad 212 to each of which a terminal functioning as the power supply output terminal VOUT is connected are connected to an output power supply pattern which is a wiring pattern. The output power supply pattern is a continuous wiring pattern including the pad 206, the pad 211, and the pad 212. A power supply voltage is output from each pad via the output power supply pattern. In addition, the fifth terminal 105 (the first setting terminal Cont1) of the part A is a terminal connectable to the sixth terminal 106 (the power supply output terminal VOUT). Accordingly, the pad 205 is also connected to the output power supply pattern which is a wiring pattern. In a case in which a control signal of “Low” is input to the third terminal 103, a dropping time of the output voltage VOUT can be shortened by connecting the fifth terminal 105 of the part A to the output voltage VOUT. In this manner, pads to which terminals having the same function, and terminals that have different functions but are connectable to each other are connected to the same wiring pattern.

In the case of mounting the part A, the fifth terminal 105 (the first setting terminal Cont1) is linked directly to the output power supply pattern by the pad 205. That is, the fifth terminal 105 (the first setting terminal Cont1) is treated as the same node as the pad 211, the pad 212, and the pad 206 to which the output power supply pattern is connected. Thus, the pads for the part A that are connected to the same wiring pattern are placed between the pads for the part B, and the pads for the part B that are connected to the same wiring pattern are placed between the pads for the part A.

With this configuration, space saving that reduces an area taken up by the part A and the part B on the circuit board is achieved at the same time as securing of an appropriate size for the output power supply pattern. In the example of FIG. 2, the pad 206 to which a terminal of the part A is to be connected and the pad 211 to which a terminal of the part B is to be connected are placed at the same position in the second direction. The above-mentioned effect of space saving is attainable even when the pad 206 and the pad 211 are placed at positions different from each other in the second direction. In addition, wiring patterns of power supply systems, in particular, are preferred to be low in resistance value, and a resistance lowering effect obtained by sharing the output power supply pattern is accordingly notable.

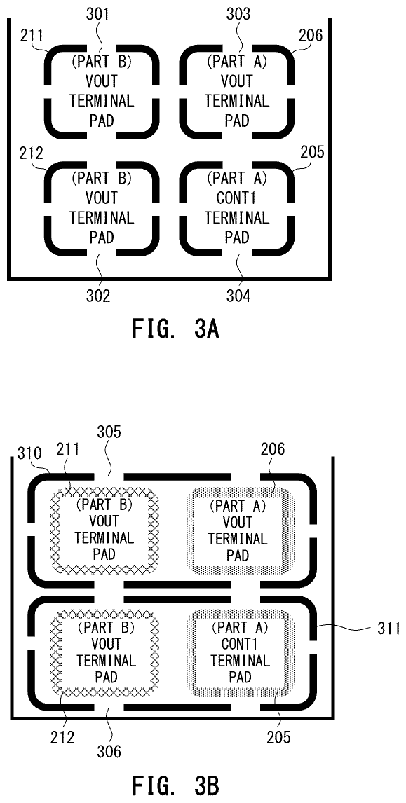

FIG. 3A and FIG. 3B are explanatory diagrams of arrangement of the pads connected to the output power supply pattern. Arrangement of the pad 205, the pad 206, the pad 211, and the pad 212 is illustrated in FIG. 3A. FIG. 3B is an explanatory diagram of pads each of which encompasses pads adjacent to each other.

In FIG. 3A, the pad 211 to which the first terminal 101 of the part B is to be connected is connected at a clearance gap 301 to the output power supply pattern. In the at least one embodiment, the clearance gap 301 is provided in each of places above, below, to the left of, and to the right of the pad 211, four places in total. The clearance gap 301 enable the pad 211 to form a thermal land. The pad 212 to which the second terminal 102 of the part B is to be connected is connected at a clearance gap 302 to the output power supply pattern. In the at least one embodiment, the clearance gap 302 is provided in each of places above, below, to the left of, and to the right of the pad 212, four places in total. The clearance gap 302 enable the pad 212 to form a thermal land.

The pad 206 to which the sixth terminal 106 of the part A is to be connected is connected at a clearance gap 303 to the output power supply pattern. In the at least one embodiment, the clearance gap 303 is provided in each of places above, below, to the left of, and to the right of the pad 206, four places in total. The clearance gap 303 enable the pad 206 to form a thermal land. The pad 205 to which the fifth terminal 105 of the part A is to be connected is connected at a clearance gap 304 to the output power supply pattern. In the at least one embodiment, the clearance gap 304 is provided in each of places above, below, to the left of, and to the right of the pad 205, four places in total. The clearance gap 304 enable the pad 205 to form a thermal land. In the example illustrated in FIG. 3A, the output power supply pattern is thus formed as a wiring pattern that establishes electrical connection for a plurality of pads.

In FIG. 3B, the pad 211 and the pad 206 are contained in one pad 310. That is, the pad 211 and the pad 206 do not individually have resist openings, and the pad 310 is the resist opening portion. The resist is an example of a dielectric layer covering a wiring pattern. An opening formed in the resist defines a region that functions as a pad. That is, an opening in the resist defines a part of the wiring pattern which is a conductor as a region to which a terminal is to be connected. The pad 310 is connected at a clearance gap 305 to the output power supply pattern. In the at least one embodiment, the clearance gap 305 is provided in each of two upper places, two lower places, one left place, and one right place, six places in total. The clearance gap 305 enables the pad 310 to form a thermal land. The pad 212 and the pad 205 are contained in a pad 311. That is, the pad 212 and the pad 205 do not individually have resist openings, and the pad 311 is the resist opening portion. The pad 311 is connected at a clearance gap 306 to the output power supply pattern. In the at least one embodiment, the clearance gap 306 is provided in each of two upper places, two lower places, one left place, and one right place, six places in total. The clearance gap 306 enables the pad 311 to form a thermal land. In a case in which a dielectric layer such as a resist is not used, outer edges of the pads are defined by patterning a layer of the conductor.

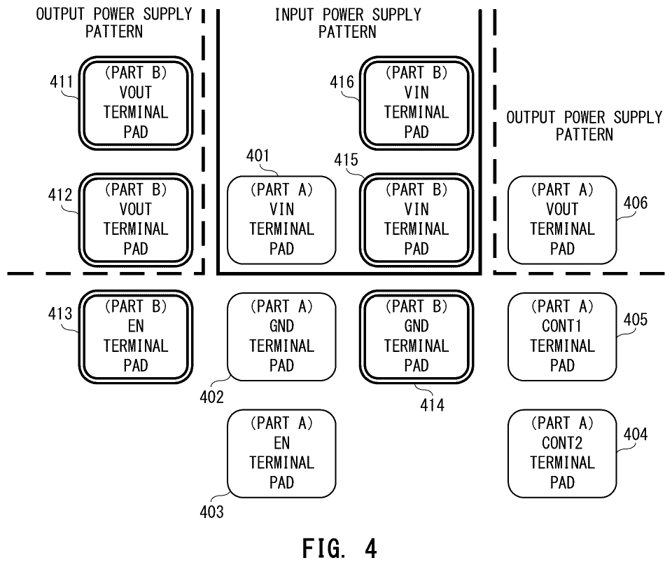

FIG. 4 is an explanatory diagram of another example of the region for mounting the electronic part 100. As in FIG. 2, exemplary arrangement of pads is illustrated in FIG. 4. In FIG. 4, pads 401, 402, 403, 404, 405, and 406 for the part A and pads 411, 412, 413, 414, 415, and 416 for the part B are placed.

The first terminal 101 of the part A is to be connected to the pad 401. The second terminal 102 of the part A is to be connected to the pad 402. The third terminal 103 of the part A is to be connected to the pad 403. The fourth terminal 104 of the part A is to be connected to the pad 404. The fifth terminal 105 of the part A is to be connected to the pad 405. The sixth terminal 106 of the part A is to be connected to the pad 406. The first terminal 101 of the part B is to be connected to the pad 411. The second terminal 102 of the part B is to be connected to the pad 412. The third terminal 103 of the part B is to be connected to the pad 413. The fourth terminal 104 of the part B is to be connected to the pad 414. The fifth terminal 105 of the part B is to be connected to the pad 415. The sixth terminal 106 of the part B is to be connected to the pad 416.

The region for mounting the part A and the region for mounting the part B are not the same, and are provided so as to partially overlap with each other and avoid overlapping in the rest. Accordingly, the pads 414 to 416 to which the terminals of the part B are to be connected are placed between the pads 401 to 403 and the pads 404 to 406 to which the terminals of the part A are to be connected. The pads 401 to 403 to which the terminals of the part A are to be connected are also placed between the pads 411 to 413 and the pads 414 to 416 to which the terminals of the part B are to be connected. The pads 401 to 406 to which the terminals of the part A are to be connected and the pads 411 to 416 to which the terminals of the part B are to be connected are arranged so as to be staggered from each other in a direction parallel to the sides along which the terminals are provided (a direction in which the terminals are aligned: the second direction). In FIG. 4, the pads 411 to 416 to which the part B is to be connected are staggered from the pads 401 to 406 to which the part A is to be connected, by placing the pads 411 to 416 one pad above the pads 401 to 406. This pad arrangement is feasible because the part A and the part B are mounted on the circuit board exclusively of each other.

The pad 401, the pad 415, and the pad 416 to each of which a terminal functioning as the power supply input terminal VIN is connected are connected to an input power supply pattern. A power supply voltage is supplied to each pad by way of the input power supply pattern. The pad 406, the pad 411, and the pad 412 to each of which a terminal functioning as the power supply output terminal VOUT is connected are connected to an output power supply pattern. A power supply voltage is output from each pad via the output power supply pattern.

The arrangement in FIG. 4 enables separate setting of the pad 405 to which the fifth terminal 105 (the first setting terminal Cont1) is to be connected. In FIG. 4, when the pads 401 to 406 to which the terminals of the part A are to be connected and the pads 411 to 416 to which the terminals of the part B are to be connected are not staggered from each other in the direction in which the terminals of the electronic parts are aligned, an appropriate size cannot be secured for a ground pattern connected to the pads 402 and 414 which are to be grounded. The pads 402 and 414 which are to be grounded are brought next to each other by staggering the pads 411 to 416 to which the terminals of the part B are to be connected, relative to the pads 401 to 406 to which the terminals of the part A are to be connected, in the direction in which the terminals of the electronic parts are aligned. An appropriate size is thus secured for the grounding pattern to be connected to the pads 402 and 414 in a shared manner. The pads 401 and 415 and the pad 416 are formed on the input power supply pattern. Accordingly, space saving that reduces the area taken up by the part A and the part B on the circuit board is achieved at the same time as securing of an appropriate size for the input power supply pattern.

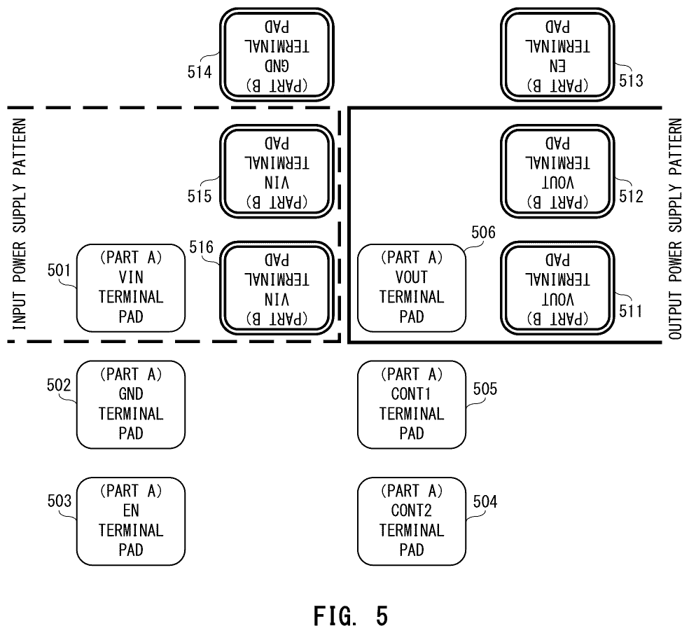

FIG. 5 is an explanatory diagram of another example of the region for mounting the electronic part 100. As in FIG. 2, exemplary arrangement of pads is illustrated in FIG. 5. In FIG. 5, pads 501, 502, 503, 504, 505, and 506 for the part A and pads 511, 512, 513, 514, 515, and 516 for the part B are placed.

The first terminal 101 of the part A is to be connected to the pad 501. The second terminal 102 of the part A is to be connected to the pad 502. The third terminal 103 of the part A is to be connected to the pad 503. The fourth terminal 104 of the part A is to be connected to the pad 504. The fifth terminal 105 of the part A is to be connected to the pad 505. The sixth terminal 106 of the part A is to be connected to the pad 506. The first terminal 101 of the part B is to be connected to the pad 511. The second terminal 102 of the part B is to be connected to the pad 512. The third terminal 103 of the part B is to be connected to the pad 513. The fourth terminal 104 of the part B is to be connected to the pad 514. The fifth terminal 105 of the part B is to be connected to the pad 515. The sixth terminal 106 of the part B is to be connected to the pad 516.

The region for mounting the part A and the region for mounting the part B are not the same, and are provided so as to partially overlap with each other and avoid overlapping in the rest. The terminals of the part A and the part B are directed in opposite directions when the part A and the part B are mounted. Accordingly, the pads 514 to 516 to which the terminals of the part B are to be connected are placed between the pads 501 to 503 and the pads 504 to 506 to which the terminals of the part A are to be connected. The pads 504 to 506 to which the terminals of the part A are to be connected are also placed between the pads 511 to 513 and the pads 514 to 516 to which the terminals of the part B are to be connected. The pads 501 to 506 to which the terminals of the part A are to be connected and the pads 511 to 516 to which the terminals of the part B are to be connected are arranged so as to be staggered from each other in a direction parallel to the sides along which the terminals are provided (a direction in which the terminals are aligned: the second direction). In FIG. 5, the pads 511 to 516 to which the part B is to be connected are staggered from the pads 501 to 506 to which the part A is to be connected, by placing the pads 511 to 516 two pads above the pads 501 to 506. This pad arrangement is feasible because the part A and the part B are mounted on the circuit board exclusively of each other.

The pad 501, the pad 515, and the pad 516 to each of which a terminal functioning as the power supply input terminal VIN is connected are connected to an input power supply pattern. A power supply voltage is supplied to each pad by way of the input power supply pattern. The pad 506, the pad 511, and the pad 512 to each of which a terminal functioning as the power supply output terminal VOUT is connected are connected to an output power supply pattern. A power supply voltage is output from each pad via the output power supply pattern. With this pad arrangement, space saving that reduces the area taken up by the part A and the part B on the circuit board is achieved at the same time as securing of an appropriate size for the input power supply pattern and an appropriate size for the output power supply pattern on the same surface on the circuit board.

As illustrated in FIG. 2, FIG. 4, and FIG. 5, arrangement of the pads provided on the circuit board is based on the functions of the terminals of the part A and the part B that are connected to the pads. For example, in FIG. 2, pads sharing the same function as the function of terminals to be connected thereto are brought next to each other by placing the pads to be connected to the part B so as to sandwich the pads to be connected to the part A. In FIG. 4, pads sharing the same function as the function of terminals to be connected thereto are brought next to each other by placing the pads to be connected to the part A and the pads to be connected to the part B so as to be staggered from each other in the direction in which the terminals are aligned. In FIG. 5, pads sharing the same function as the function of terminals to be connected thereto are brought next to each other by reversing a direction of the pads to be connected to the part A and a direction of the pads to be connected to the part B from each other, and placing the pads to be connected to the part A and the pads to be connected to the part B so as to be staggered from each other in the direction in which the terminals are aligned. The arrangement that places, next to each other, pads to which terminals of the same function are to be connected makes it easy to include a plurality of pards in one pad as in FIG. 3B.

Arranging the pads for the part A and the pads for the part B so that pads sharing the same function as the function of terminals to be connected thereto are next to each other in this manner simplifies layout of the wiring patterns (the input power supply pattern, the output power supply pattern, and the ground pattern). The arrangement also facilitates securing of appropriate sizes for the wiring patterns. With appropriate sizes of the wiring patterns secured, supply of a power supply voltage to the electronic part mounted on the circuit board is stabilized and a ground potential is stabilized, resulting in stable operation of the electronic part.

### Image Forming Apparatus

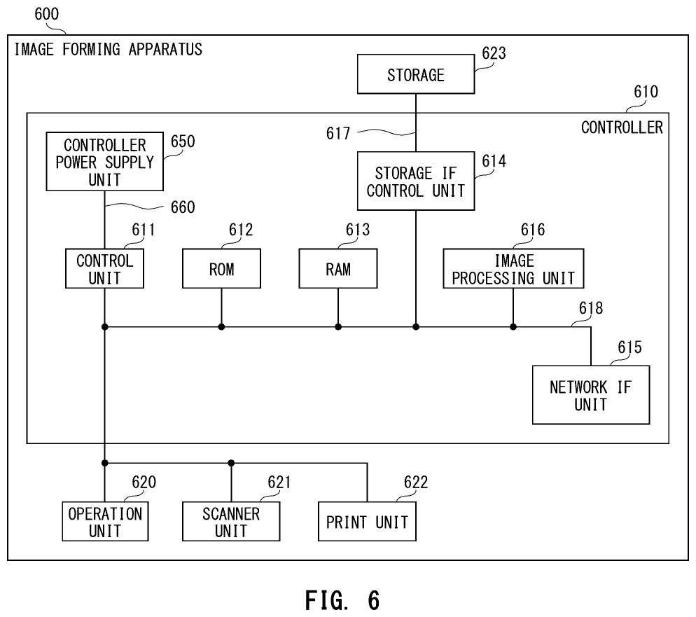

FIG. 6 is an explanatory diagram of an image forming apparatus in which a circuit board having the configuration described above is installed. This image forming apparatus 600 includes a controller 610, an operation unit 620, a scanner unit 621, a print unit 622, and a storage 623. The circuit board described above is installed in, for example, the controller 610.

The controller 610 is an information processing apparatus including a control unit 611, a read-only memory (ROM) 612, and a random access memory (RAM) 613. The controller 610 includes a controller power supply unit 650, an image processing unit 616, a storage interface (IF) control unit 614, and a network IF unit 615. The control unit 611, the ROM 612, the RAM 613, the image processing unit 616, the storage IF control unit 614, and the network IF unit 615 are connected to one another via a bus 618 in a manner that allows communication to and from one another. The controller 610 controls overall operation of the image forming apparatus 600.

The control unit 611 is a processing apparatus including at least one processor, for example, a central processing unit (CPU), a micro processing unit (MPU), or a graphics processing unit (GPU). The control unit 611 executes a computer program stored on the ROM 612, to thereby control operation of the components of the controller 610, the operation unit 620, the scanner unit 621, the print unit 622, and the storage 623. The RAM 613 functions as a main memory in a case where the control unit 611 executes processing.

The network IF unit 615 is a communication interface for communication of the image forming apparatus 600 to and from an external apparatus such as a personal computer. The image processing unit 616 performs predetermined image processing on image data. The image data is, for example, image data that represents an image read by the scanner unit 621 from an original, image data acquired by the network IF unit 615 from an external apparatus, or image data acquired by the storage IF control unit 614 from the storage 623. The scanner unit 621 is an image reading apparatus for reading an original.

The storage IF control unit 614 is a communication interface for communication to and from the storage 623. The storage IF control unit 614 is a bridge circuit for converting data of the bus 618 into data transmitted and received via a bus 617, which is connected to the storage 623. The storage 623 is a non-volatile storage device such as a hard disk drive (HDD), a solid state drive (SSD), or a universal serial bus (USB) memory.

The print unit 622 is an image forming unit which prints, for example, an image based on image data that has been processed by image processing in the image processing unit 616, on a recording material in the form of a sheet or the like. The operation unit 620 is a user interface including an input interface and an output interface. The input interface is a set of various key buttons, a touch panel, or the like. The output interface is a display, a speaker, and the like. A user may input various instructions and settings to the image forming apparatus 600 via the operation unit 620.

The controller power supply unit 650 supplies a power supply voltage to electronic parts included in the controller 610. The controller power supply unit 650 is controlled by the control unit 611. The control unit 611 and the controller power supply unit 650 are directly connected to each other by a control signal line group 660, without intervention of the bus 618.

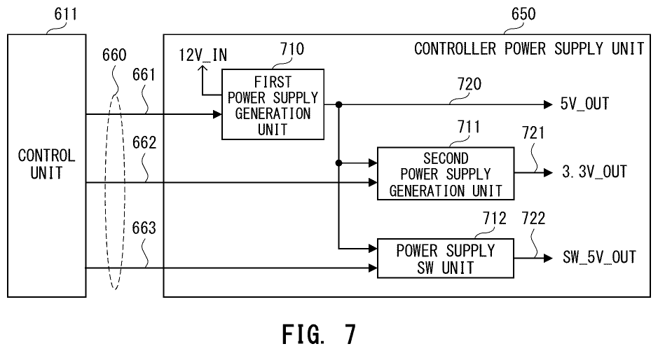

FIG. 7 is a configuration diagram of the controller power supply unit 650. The controller power supply unit 650 generates, from an input power supply voltage of 12 V supplied thereto, an output power supply voltage of 5 V and an output power supply voltage of 3.3 V, and outputs the generated voltages. For that purpose, the controller power supply unit 650 includes a first power supply generation unit 710, a second power supply generation unit 711, and a power supply SW unit 712. The control signal line group 660 which connects the controller power supply unit 650 and the control unit 611 to each other is used for transmission of control signals 661, 662, and 663.

The first power supply generation unit 710 is a power supply circuit that generates an output power supply voltage of 5 V from an input power supply voltage of 12 V. The output power supply voltage of 5V is output as 5V_OUT 720. The first power supply generation unit 710 is a general electronic device, for example, a DC-to-DC converter. The first power supply generation unit 710 outputs the output power supply voltage (5V_OUT 720) when acquiring the control signal 661 of a predetermined logical value (for example, “High”) from the control unit 611. The first power supply generation unit 710 cuts off output of the output power supply voltage (5V_OUT 720) when acquiring the control signal 661 of a reverse logical value (for example, “Low”) from the control unit 611.

The voltage 5V_OUT 720 is supplied to electronic parts of the controller 610 that are driven on a power supply of 5 V. In a case of suppressing power consumption of the controller 610, the output of 5V_OUT 720 is not cut off.

The second power supply generation unit 711 is a power supply circuit that generates, from the output power supply voltage of 5V (5V_OUT 720) generated in the first power supply generation unit 710, an output power supply voltage of 3.3 V. The output power supply voltage of 3.3 V is output as 3.3V_OUT 721. The second power supply generation unit 711 is a general electronic device, for example, a DC-to-DC converter. The second power supply generation unit 711 outputs the output power supply voltage (3.3V_OUT 721) when acquiring the control signal 662 of a predetermined logical value (for example, “High”) from the control unit 611. The second power supply generation unit 711 cuts off output of the output power supply voltage (3.3V_OUT 721) when acquiring the control signal 662 of a reverse logical value (for example, “Low”) from the control unit 611.

The voltage 3.3V_OUT 721 is supplied to electronic parts of the controller 610 that are driven on a power supply of 3.3 V. In a case of suppressing power consumption of the controller 610, the output of 3.3V_OUT 721 is not cut off.

The power supply SW unit 712 is a power supply circuit that generates, from the output power supply voltage of 5V (5V_OUT 720) generated in the first power supply generation unit 710, an output power supply voltage of 5 V. The output power supply voltage of 5V is output as SW_5V_OUT 722. The power supply SW unit 712 is a general electronic device, for example, a load switch. The power supply SW unit 712 outputs the output power supply voltage (SW_5V_OUT 722) when acquiring the control signal 663 of a predetermined logical value (for example, “High”) from the control unit 611. The power supply SW unit 712 cuts off output of the output power supply voltage (SW_5V_OUT 722) when acquiring the control signal 663 of a reverse logical value (for example, “Low”) from the control unit 611.

The voltage SW_5V_OUT 722 is supplied to electronic parts of the controller 610 that are driven on a power supply of 5 V. In a case of suppressing power consumption of the controller 610, the output of SW_5V_OUT 722 is cut off.

The electronic part of FIG. 1A and FIG. 1B is used in, for example, the controller power supply unit 650 of the controller 610. For example, the part A and the part B described above are usable in the controller power supply unit 650. Accordingly, a circuit board of the controller 610 on which the controller power supply unit 650 is mounted has a pad arrangement such as the arrangements described with reference to FIG. 2 to FIG. 5. The part A and the part B are, for example, a regular product and a replacement and, in a case where the regular product is unavailable, the replacement is used in manufacturing of the controller 610. As another example, the part A and the part B are an initial product mounted at the time of manufacture and an improved product replacing the initial product after being distributed. As still another example, the part A and the part B are parts having different characteristics that are prepared in order to change specifications of the image forming apparatus.

The electronic part of FIG. 1A and FIG. 1B may be, for example, at least one of the first power supply generation unit 710, the second power supply generation unit 711, and the power supply SW unit 712 of the controller power supply unit 650. Each of the first power supply generation unit 710, the second power supply generation unit 711, and the power supply SW unit 712 is, for example, one of the part A and the part B described above. Then, a circuit board of the controller power supply unit 650 on which the first power supply generation unit 710, the second power supply generation unit 711, and the power supply SW unit 712 are mounted includes a pad arrangement such as the arrangements described with reference to FIG. 2 to FIG. 5.

The electronic part of FIG. 1A and FIG. 1B can be any electronic part mounted in the controller 610, other than the electronic parts in the controller power supply unit 650. That is, the electronic part of FIG. 1A and FIG. 1B may be used in the control unit 611, the ROM 612, the RAM 613, the image processing unit 616, the storage IF control unit 614, and the network IF unit 615. Then, the circuit board of the controller 610 includes, as required, a pad arrangement such as the arrangements described with reference to FIG. 2 to FIG. 5.

According to the present disclosure as described above, the circuit board can be reduced in size.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-134362, filed Aug. 9, 2024, which is hereby incorporated by reference herein in its entirety.

What is claimed is:

1. A circuit board having a first surface, comprising:
a first electronic part mounted on the first surface and comprising a first terminal and a second terminal;
a first pad which is placed on the first surface and to which the first terminal of the first electronic part is connected;
a second pad which is placed on the first surface and to which the second terminal of the first electronic part is connected; and
a third pad and a fourth pad which are placed on the first surface and to which terminals of a second electronic part are connectable, the second electronic part being a different part from the first electronic part,
wherein the third pad is placed between the first pad and the second pad in a first direction along the first surface,
wherein the second pad is placed between the third pad and the fourth pad in the first direction, and
wherein the third pat is not in contact with the first electronic part.

2. The circuit board according to claim 1, further comprising a wiring pattern configured to establish electrical connection of the second pad and the third pad.

3. The circuit board according to claim 2, wherein the wiring pattern is supplied with a power supply voltage output from one of the first electronic part and the second electronic part.

4. The circuit board according to claim 2, wherein the wiring pattern is supplied with a power supply voltage to be input to one of the first electronic part and the second electronic part.

5. The circuit board according to claim 1, further comprising:
a continuous wiring pattern including the second pad and the third pad; and
an insulation layer partially covering the continuous wiring pattern,
wherein a first opening and a second opening are provided in the insulation layer through which the continuous wiring pattern is exposed, and
wherein the first opening defines the second pad and the second opening defines the third pad.

6. The circuit board according to claim 5, wherein the wiring pattern is supplied with a power supply voltage output from one of the first electronic part and the second electronic part.

7. The circuit board according to claim 5, wherein the wiring pattern is supplied with a power supply voltage to be input to one of the first electronic part and the second electronic part.

8. The circuit board according to claim 1, further comprising:
a fifth pad and a sixth pad which are placed on the first surface and to which terminals of the first electronic part are to be connected; and
a seventh pad and an eighth pad which are placed on the first surface and to which terminals of the second electronic part are to be connected,
wherein the seventh pad is placed between the fifth pad and the sixth pad in the first direction, and
wherein the sixth pad is placed between the seventh pad and the eighth pad in the first direction.

9. The circuit board according to claim 8,
wherein the first pad, the second pad, the third pad, and the fourth pad are placed at the same position in a second direction intersecting the first direction, and
wherein the fifth pad, the sixth pad, the seventh pad, and the eighth pad are placed at the same position in the second direction.

10. The circuit board according to claim 8,
wherein the first pad, the second pad, the third pad, and the fourth pad are placed at the same position in a second direction intersecting the first direction,
wherein the fifth pad and the sixth pad are placed at the same position as each other in the second direction, and
wherein, in the second direction, the seventh pad and the eighth pad are placed at the same position as each other, and are placed at a position different from the position of the fifth pad and the sixth pad.

11. The circuit board according to claim 1, wherein the first pad, the second pad, the third pad, and the fourth pad are placed at the same position in a second direction intersecting the first direction.

12. An image forming apparatus comprising:
an image forming unit configured to form an image on a recording material; and
a controller configured to control the image forming unit,
wherein the controller includes a circuit board on which a first electronic part is mounted and a second electronic part is not mounted, the circuit board having a first surface,
wherein the first electronic part is mounted on the first surface and includes a first terminal and a second terminal,
wherein the circuit board includes
a first pad which is placed on the first surface and to which the first terminal of the first electronic part is connected,
a second pad which is placed on the first surface and to which the second terminal of the first electronic part is connected, and
a third pad and a fourth pad which are placed on the first surface and to which terminals of a second electronic part are connectable,
wherein the third pad is placed between the first pad and the second pad in a first direction along the first surface,
wherein the second pad is placed between the third pad and the fourth pad in the first direction, and
wherein the third pat is not in contact with the first electronic part.
